(19) United States
(12) Patent Application Publication
(10) Pub. No.: US 2016/0248423 A1
(43) Pub. Date: Aug. 25, 2016

(54) FEEDTHROUGH SIGNAL TRANSMISSION CIRCUIT AND APPARATUS AND METHOD UTILIZING PERMANENTLY ON BUFFER AND SWITCHABLE NORMAL BUFFER

(71) Applicant: MEDIATEK INC., Hsin-chu (TW)

(72) Inventors: Chien-Pang Lu, Hsinchu County (TW); Yu-Tung Chang, Hsinchu City (TW)

(21) Appl. No.: 15/145,779

(22) Filed: May 3, 2016

Related U.S. Application Data
(63) Continuation-in-part of application No. 14/226,781, filed on Mar. 26, 2014.
(60) Provisional application No. 62/184,499, filed on Jun. 25, 2015.

(51) Int. Cl. H03K 17/687; H05K 1/18; H05K 1/03

(52) U.S. Cl. CPC H03K 17/6872; H05K 1/0306; H05K 1/18

(57) ABSTRACT

A feedthrough signal transmission apparatus, fabricated on a single silicon, includes a plurality of feedthrough signal transmission circuits and a permanently on control cell that is coupled to the feedthrough signal transmission circuits, where each feedthrough signal transmission circuit of the feedthrough signal transmission circuits may include at least one sub-circuit that is kept in a power on state when the sub-circuit performs feedthrough signal transmission. For example, and the sub-circuit may include a permanently on-for-feedthrough repeater (e.g. a repeater that is kept in the power on state when the repeater performs feedthrough signal transmission). In addition, the permanently on control cell may be configured to maintain the power on state of the sub-circuit when the sub-circuit performs feedthrough signal transmission. For example, sub-circuits of the feedthrough signal transmission circuits are located at grid-based locations, respectively.

### CROSS REFERENCE TO RELATED APPLICATION

This application is a continuation in part application and claims the benefit of U.S. Non-provisional application Ser. No. 14/226,781, which was filed on Mar. 26, 2014 and is included herein by reference. In addition, this application claims the benefit of U.S. Provisional Application No. 62/184,499, which was filed on Jun. 25, 2015 and is included herein by reference.

### BACKGROUND

The disclosed embodiments of the invention relate to a feedthrough signal transmission circuit, apparatus, and method, and more particularly, to a feedthrough signal transmission circuit and apparatus and method utilizing at least one permanently on buffer and a switchable normal buffer which can be selectively powered off.

A feedthrough is a conductor used to carry a signal through a printed circuit board (PCB). Feedthroughs can be divided into power and instrumentation categories, wherein power feedthroughs are used to carry either high current or high voltage, and instrumentation feedthroughs are used to carry electrical signals which are normally low current or voltage.

Please refer to FIG. 1, which shows a feedthrough in a circuit design according to the related art. As shown in FIG. 1, the circuitry 100 comprises three circuits 10, 20, 30 belonging to different partition/block/power domains. When the circuit 20 transmits signals to the circuit 10 or receives signals from the circuit 10, those signals have to go through the circuit 30 between the circuits 10 and 20. For this reason, the circuit 30 has to be designed as a permanently on type; otherwise, the signal transmission between the circuits 10 and 20 may fail. If the circuit 30 were powered off, the circuit 20 would not be able to transmit signals to the circuit 10 or receive signals from the circuit 10. Using a permanently on cell, however, will raise the power consumption. Specifically, when a source block preceding the feedthrough circuit and a sink block following the feedthrough circuit are powered down, the feedthrough circuit will remain powered on, which inevitably results in leakage power. Therefore, there is a need for a novel feedthrough design which uses a permanently on cell but wherein the circuit can be powered off.

### SUMMARY

In accordance with exemplary embodiments of the invention, a feedthrough signal transmission circuit and apparatus and method utilizing at least one permanently on buffer and a switchable normal buffer which can be selectively powered off are proposed to solve the above-mentioned problem.

According to a first aspect of the invention, a feedthrough signal transmission circuit is disclosed. The feedthrough signal transmission circuit has a first permanently on cell and a cell controlling unit. The first permanently on cell is arranged to transmit a first control signal. The cell controlling unit is coupled to the first permanently on cell, and has a power switch and a plurality of buffers. The power switch is coupled to the first permanently on cell, and is arranged to receive the first control signal and selectively conduct a power supply signal according to the first control signal. The buffers are coupled to the power switch, wherein each of the buffers is arranged to buffer a data input only when powered by the power supply signal output from the power switch.

According to a second aspect of the invention, a feedthrough signal transmission method is disclosed. The feedthrough signal transmission method includes: transmitting a first control signal through a first permanently on cell; and referring to the first permanently on cell to selectively provide a power supply signal to a plurality of buffers, wherein each of the buffers is arranged to buffer a data input only when powered by the power supply signal.

According to a third aspect of the invention, a feedthrough signal transmission circuit is disclosed. The feedthrough signal transmission circuit includes a plurality of permanently on cells and a cell controlling unit. The permanently on cells are arranged to transmit a plurality of control signals, respectively. The cell controlling unit is coupled to the permanently on cells, and has a plurality of power switches and a plurality of buffers. The power switches are coupled to the permanently on cells, respectively, wherein each of the power switches is arranged to receive a corresponding control signal, and selectively conduct a power supply signal according to the corresponding control signal. The buffers are coupled to the power switches, respectively, wherein each of the buffers is arranged to buffer a data input only when powered by the power supply signal output from a corresponding power switch.

According to an aspect of the invention, a feedthrough signal transmission apparatus is disclosed. For example, the feedthrough signal transmission apparatus may be fabricated on an integrated circuit (IC) such as a single silicon, and may comprise a plurality of feedthrough signal transmission circuits, wherein each feedthrough signal transmission circuit of the feedthrough signal transmission circuits may comprise at least one sub-circuit that is kept in a power on state when the sub-circuit performs feedthrough signal transmission, and the sub-circuit may comprises a permanently on-for-feedthrough repeater (e.g. a repeater that is kept in the power on state when the repeater performs feedthrough signal transmission). For example, the feedthrough signal transmission apparatus may further comprise a permanently on control cell that is coupled to the plurality of feedthrough signal transmission circuits, where the permanently on control cell may be configured to maintain the power on state of the sub-circuit when the sub-circuit performs feedthrough signal transmission. In addition, sub-circuits of the plurality of feedthrough signal transmission circuits may be located at grid-based locations on a chip area of the single silicon, respectively.

In some embodiments, a feedthrough signal transmission circuit is disclosed. For example, the feedthrough signal transmission circuit may comprise a first permanently on cell and a cell controlling unit. The first permanently on cell is arranged to transmit a first control signal. The cell controlling unit is coupled to the first permanently on cell, and has a power switch and a plurality of buffers. The power switch is coupled to the first permanently on cell, and is arranged to receive the first control signal and selectively conduct a power supply signal according to the first control signal. The buffers are coupled to the power switch, wherein each of the buffers is arranged to buffer a data input only when powered by the power supply signal output from the power switch. In addition, the feedthrough signal transmission circuit may be one of a plurality of feedthrough signal transmission circuits in an integrated circuit (IC), and sub-circuits of a set of feedthrough signal transmission circuits within the plurality of feedthrough signal transmission circuits may be located at grid-based locations on a chip area of the IC, respectively, wherein the set of feedthrough signal transmission circuits may comprise the one of the plurality of feedthrough signal transmission circuits.

According to another aspect of the invention, a feedthrough signal transmission method is disclosed. For example, the feedthrough signal transmission method be applied to a feedthrough signal transmission apparatus that is fabricated on an integrated circuit (IC) such as a single silicon, and may comprise: transmitting a control signal to a permanently on control cell, wherein the feedthrough signal transmission apparatus comprises a plurality of feedthrough signal transmission circuits and the permanently on control cell; and according to the control signal, utilizing the permanently on control cell to maintain a power on state of at least one sub-circuit of each of the feedthrough signal transmission circuits when the sub-circuit performs feedthrough signal transmission. In addition, sub-circuits of the plurality of feedthrough signal transmission circuits may be located at grid-based locations on a chip area of the single silicon, respectively. In some embodiments, a feedthrough signal transmission circuit that operates according to the above feedthrough signal transmission method is disclosed, wherein the feedthrough signal transmission circuit is one of the plurality of feedthrough signal transmission circuits.

In some embodiments, a feedthrough signal transmission method is disclosed. For example, the feedthrough signal transmission method may comprise: transmitting a first control signal through a first permanently on cell; and referring to the first permanently on cell to selectively provide a power supply signal to a plurality of buffers, wherein each of the buffers is arranged to buffer a data input only when powered by the power supply signal. In addition, the feedthrough signal transmission method is applied to a feedthrough signal transmission circuit of a plurality of feedthrough signal transmission circuits in an IC, and sub-circuits of a set of feedthrough signal transmission circuits within the plurality of feedthrough signal transmission circuits may be located at grid-based locations on a chip area of the IC, respectively, wherein the set of feedthrough signal transmission circuits may comprise the one of the plurality of feedthrough signal transmission circuits.

According to yet another aspect of the invention, a feedthrough signal transmission circuit is disclosed. The feedthrough signal transmission circuit includes a plurality of permanently on cells and a cell controlling unit. The permanently on cells are arranged to transmit a plurality of control signals, respectively. The cell controlling unit is coupled to the permanently on cells, and has a plurality of power switches and a plurality of buffers. The power switches are coupled to the permanently on cells, respectively, wherein each of the power switches is arranged to receive a corresponding control signal, and selectively conduct a power supply signal according to the corresponding control signal. The buffers are coupled to the power switches, respectively, wherein each of the buffers is arranged to buffer a data input only when powered by the power supply signal output from a corresponding power switch. In addition, the feedthrough signal transmission circuit may be one of a plurality of feedthrough signal transmission circuits in an IC, and sub-circuits of a set of feedthrough signal transmission circuits within the plurality of feedthrough signal transmission circuits may be located at grid-based locations on a chip area of the IC, respectively, wherein the set of feedthrough signal transmission circuits may comprise the one of the plurality of feedthrough signal transmission circuits.

It is an advantage of the invention that, as feedthrough buffers implemented using normal buffers can be powered down as needed, the feedthrough signal transmission circuit and the associated method can greatly reduce leakage power consumption. In addition, the sub-circuits of the set of feedthrough signal transmission circuits within the plurality of feedthrough signal transmission circuits may be located at the grid-based locations on the chip area of the IC, respectively. During a design phase of the IC, the grid-based locations can be automatically determined with a set of computer program codes, rather than being manually determined by a power engineer/designer of the IC. As a result, the invention can save time of the power engineer/designer during the design phase of the IC.

These and other objectives of the invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a feedthrough in a circuit design according to the related art.

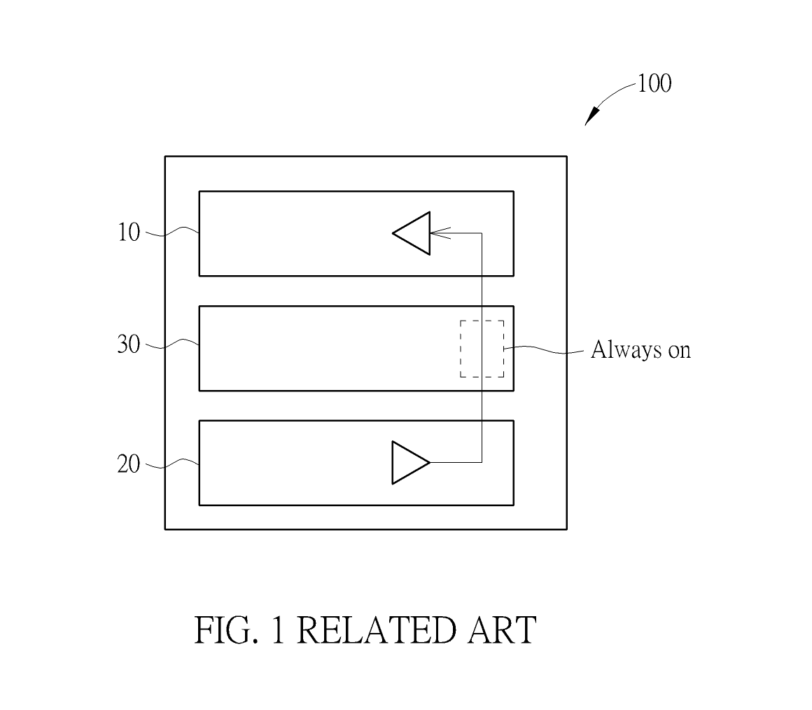

FIG. 2 shows a feedthrough signal transmission circuit according to a first embodiment of the invention.

FIG. 3 shows a feedthrough signal transmission circuit according to a second embodiment of the invention.

FIG. 4 shows a first exemplary scenario in which the feedthrough signal transmission circuit shown in FIG. 3 is used.

FIG. 5 shows a second exemplary scenario in which the feedthrough signal transmission circuit shown in FIG. 3 is used.

FIG. 6 shows a third exemplary scenario in which the feedthrough signal transmission circuit shown in FIG. 2 is used.

FIG. 7 shows a fourth exemplary scenario in which the feedthrough signal transmission circuit shown in FIG. 3 is used.

FIG. 8 shows a feedthrough signal transmission circuit according to a third embodiment of the invention.

FIG. 9 illustrates some grid locations on a chip area according to an embodiment of the invention.

FIG. 10 illustrates some grid locations on a chip area according to another embodiment of the invention.

FIG. 11 illustrates some grid-with-offset locations on a chip area according to an embodiment of the invention

FIG. 12 illustrates some grid-with-offset locations on a chip area according to another embodiment of the invention

FIG. 13 illustrates some grid-with-offset locations on a chip area according to yet another embodiment of the invention

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

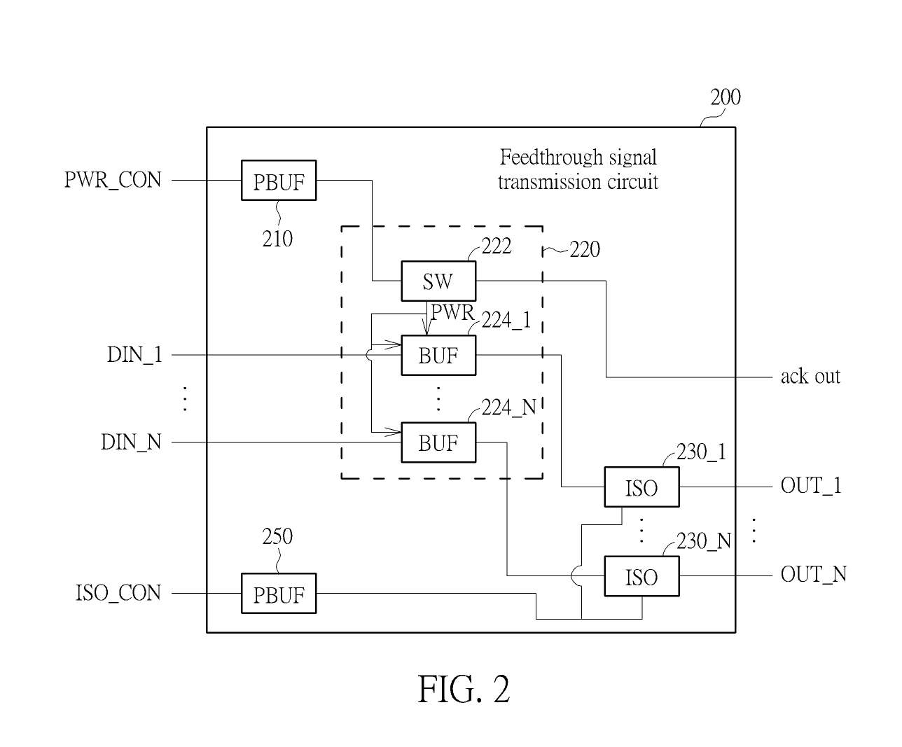

Please refer to FIG. 2, which shows a feedthrough signal transmission circuit 200 according to a first embodiment of the invention. The feedthrough signal transmission circuit 200 includes a plurality of permanently on cells 210, 250 (also denoted by ‘PBUF’), a cell controlling unit 220 and a plurality of repeaters 230_1-230_N (also denoted by ‘ISO’). The permanently on cell 210 is arranged to receive and transmit a first control source PWR_CON. The permanently on cell 250 is arranged to receive and transmit a second control source ISO CON. It should be noted that the permanently on cells 210 and 250 will remain active even when the power supply of other logic elements in a power domain where the feedthrough signal transmission circuit 200 is located is off. In this embodiment, none of the permanently on cells 210 and 250 is used to act as a feedthrough buffer. Instead, normal buffers are used to act as feedthrough buffers.

As shown in FIG. 2, the cell controlling unit 220 is coupled to the permanently on cell 210, and includes a power switch 222 (also denoted by ‘SW’) and a plurality of buffers 224_1-224_N (also denoted by ‘BUF’), where the buffers 224_1-224_N are implemented using normal buffers to serve as feedthrough buffers. It should be noted that the value of N may be any positive integer, depending upon the actual design requirement/consideration. The power switch 222 is coupled to the permanently on cell 210, and receives the first control signal PWR_CON transmitted from the permanently on cell 210. The first control signal PWR_CON acts as a switch control signal. The power switch 222 refers to the first control signal PWR_CON to selectively conduct/output a power supply signal PWR. Byway of example, but not limitation, the power switch 222 may be implemented using a multi-threshold complementary metal-oxide-semiconductor (MTCMOS) transistor. In this embodiment, a coarse-grained power gating topology is employed. Therefore, the voltage/logic level of the first control signal PWR_CON determines whether or not the MTCMOS transistor is conductive for providing the power supply signal PWR to the buffers 224_1-224_N. As the buffers 224_1-224_N are not permanently on buffers, each of the buffers 224_1-224_N will only buffer a corresponding data input when powered by the power supply signal PWR output from the power switch 222. For example, when powered by the power supply signal PWR, the buffers 224_1-224_N are arranged to buffer data inputs DIN_1-DIN_N and generate corresponding data outputs DIN_1-DIN_N, respectively.

In this embodiment, the output port of each of the buffers 224_1-224_N is coupled to one of the repeaters 230_1-230_N controlled by the second control signal ISO CON transmitted from the permanently on cell 250. By way of example, the second control signal ISO CON controls whether the repeaters 230_1-230_N are used for signal relay or used for signal isolation.

Please note that, although multiple normal buffers and multiple repeaters are illustrated in FIG. 2, the feedthrough signal transmission circuit 200 may be configured or modified to have a single normal buffer and a single repeater only.

The cell controlling unit 220 is configured in a coarse-grained fashion. A single power switch is responsible for controlling the power supply of multiple buffers. When there are data signals that need to be passed from one domain to another domain through the feedthrough signal transmission circuit 200, the first control signal PWR_CON is set to turn on the power switch 222 such that the feedthrough buffers (i.e. buffers 224_1-224_N) are powered on. Further, the second control signal ISO CON is set to make the repeaters 230_1-230_N boost data signal strength so that data signals transmitted from buffers 224_1-224_N to a next level feedthrough signal transmission circuit will not be attenuated. When there are no data signals that need to be passed from one domain to another through the feedthrough signal transmission circuit 200, the first control signal PWR_CON is set to turn off the power switch 222 such that the feedthrough buffers (i.e. buffers 224_1-224_N) are powered down. Further, the second control signal ISO CON may be set to make the repeaters 230_1-230_N isolate signals between two power domains. Compared to the conventional feedthrough design, the feedthrough buffers (i.e. buffers 224_1-224_N) of the proposed feedthrough design are allowed to be powered down. In this way, the leakage power consumption can be effectively mitigated and reduced.

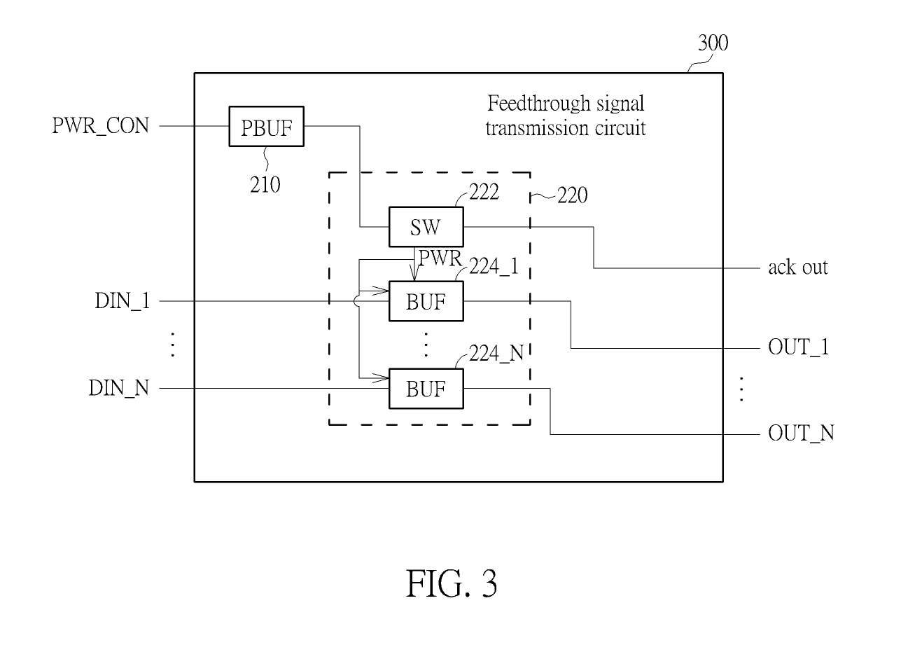

It should be noted that the repeaters 230_1-230_N and the permanently on cell 250 are optional elements. In an alternative design, the feedthrough signal transmission circuit 200 may be modified to omit the repeaters 230_1-230_N and the permanently on cell 250 without departing from the spirit of the invention. FIG. 3 shows a feedthrough signal transmission circuit according to a second embodiment of the invention. In this embodiment, the feedthrough signal transmission circuit 300 includes the aforementioned permanently on cell 210 and cell controlling unit 220, and the same objective of reducing/mitigating the leakage power consumption by powering down the feedthrough buffers is achieved.

The feedthrough signal transmission circuit 200/300 shown in FIG. 2/FIG. 3 may be used in different scenarios. Several examples are provided in the following for illustrative purposes.

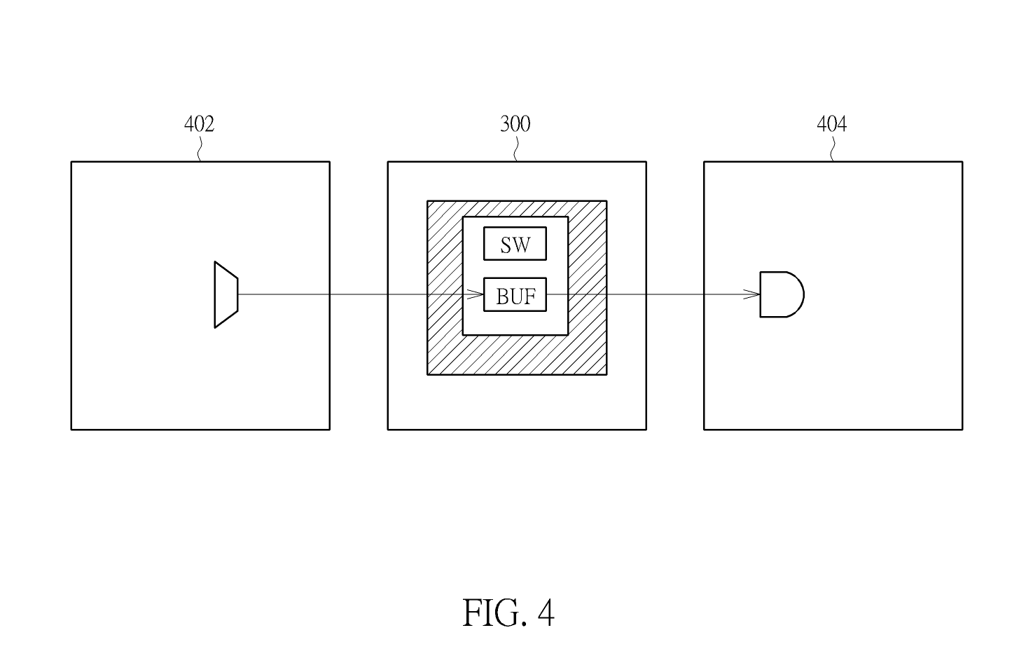

Please refer to FIG. 4, which shows a first exemplary scenario in which the feedthrough signal transmission circuit shown in FIG. 3 is used. The feedthrough signal transmission circuit 300 is coupled between two permanently on blocks 402 and 404. For clarity and simplicity, only one buffer is illustrated in the feedthrough signal transmission circuit 300. Please note that the shaded region represents an off domain, while the non-shaded region represents an on domain. In this scenario, no repeater is needed.

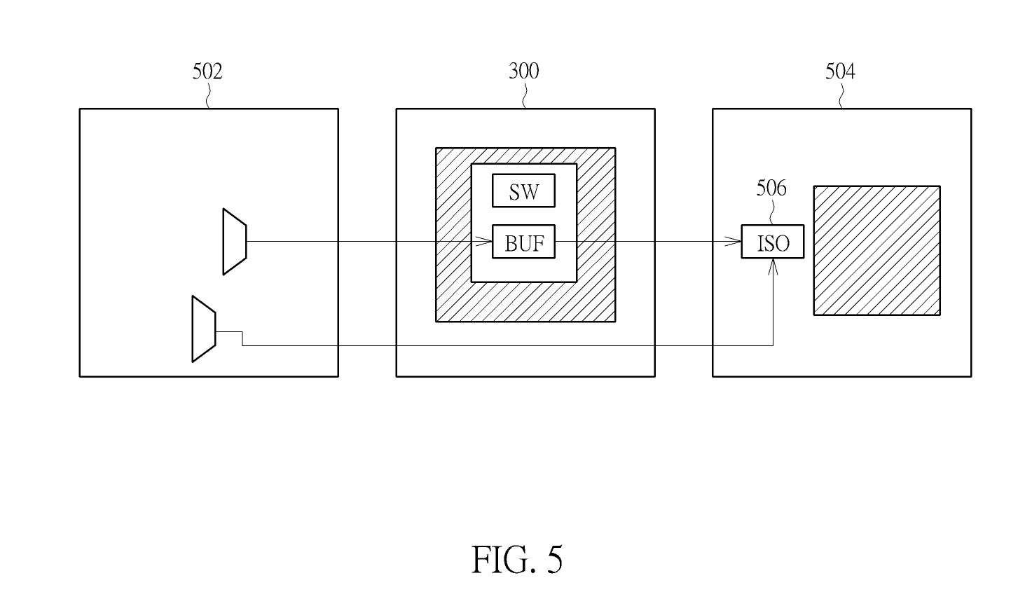

Please refer to FIG. 5, which shows a second exemplary scenario in which the feedthrough signal transmission circuit shown in FIG. 3 is used. The feedthrough signal transmission circuit 300 is coupled between a permanently on block 502 and another feedthrough signal transmission circuit 504, where the feedthrough signal transmission circuit 504 may also have the aforementioned cell controlling unit 220 implemented therein. For clarity and simplicity, only one buffer is illustrated in the feedthrough signal transmission circuit 300. Please note that the shaded region represents an off domain, while the non-shaded region represents an on domain. In this scenario, an output port of each of the buffers 224_1-224_N is coupled to a repeater 506 disposed in the feedthrough signal transmission circuit 504 following the feedthrough signal transmission circuit 300.

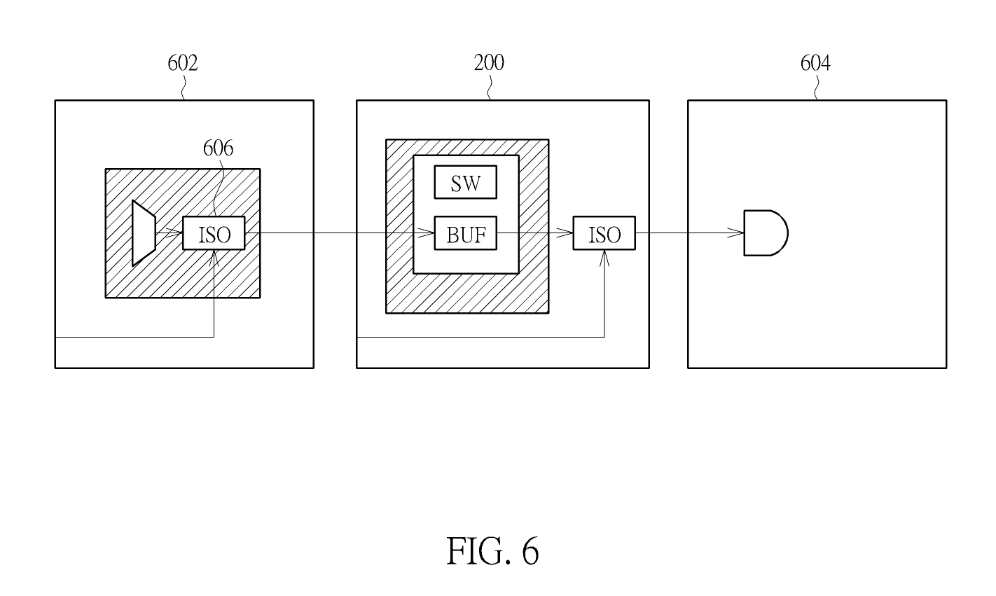

Please refer to FIG. 6, which shows a third exemplary scenario in which the feedthrough signal transmission circuit shown in FIG. 2 is used. The feedthrough signal transmission circuit 200 is coupled between another feedthrough signal transmission circuit 602 and a permanently on block 604, where the feedthrough signal transmission circuit 602 may also have the aforementioned cell controlling unit 220 implemented therein. For clarity and simplicity, only one buffer is illustrated in the feedthrough signal transmission circuit 200. Please note that the shaded region represents an off domain, while the non-shaded region represents an on domain. In this scenario, an input port of each of the buffers 224_1-224_N is coupled to a repeater 606 disposed in the feedthrough signal transmission circuit 602 preceding the feedthrough signal transmission circuit 200.

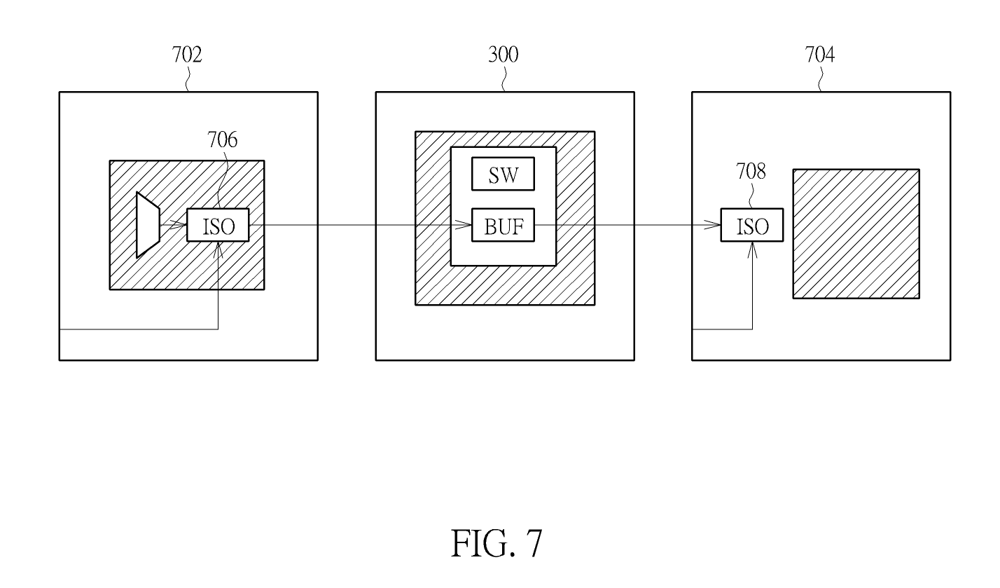

Please refer to FIG. 7, which shows a fourth exemplary scenario in which the feedthrough signal transmission circuit shown in FIG. 3 is used. The feedthrough signal transmission circuit 300 is coupled between two feedthrough signal transmission circuits 702 and 704, where each of the feedthrough signal transmission circuits 702 and 704 may also have the aforementioned cell controlling unit 220 implemented therein. For clarity and simplicity, only one buffer is illustrated in the feedthrough signal transmission circuit 300. Please note that the shaded region represents an off domain, while the non-shaded region represents an on domain. In this scenario, an input port of each of the buffers 224_1-224_N is coupled to a repeater 706 disposed in the feedthrough signal transmission circuit 702 preceding the feedthrough signal transmission circuit 300, and an output port of each of the buffers 224_1-224_N is coupled to a repeater 708 disposed in the feedthrough signal transmission circuit 704 following the feedthrough signal transmission circuit 300.

In each of the exemplary scenarios mentioned above, since the feedthrough buffers can be powered down under the control of the power switch according to actual needs, the power consumption of the feedthrough signal transmission circuit can be greatly reduced.

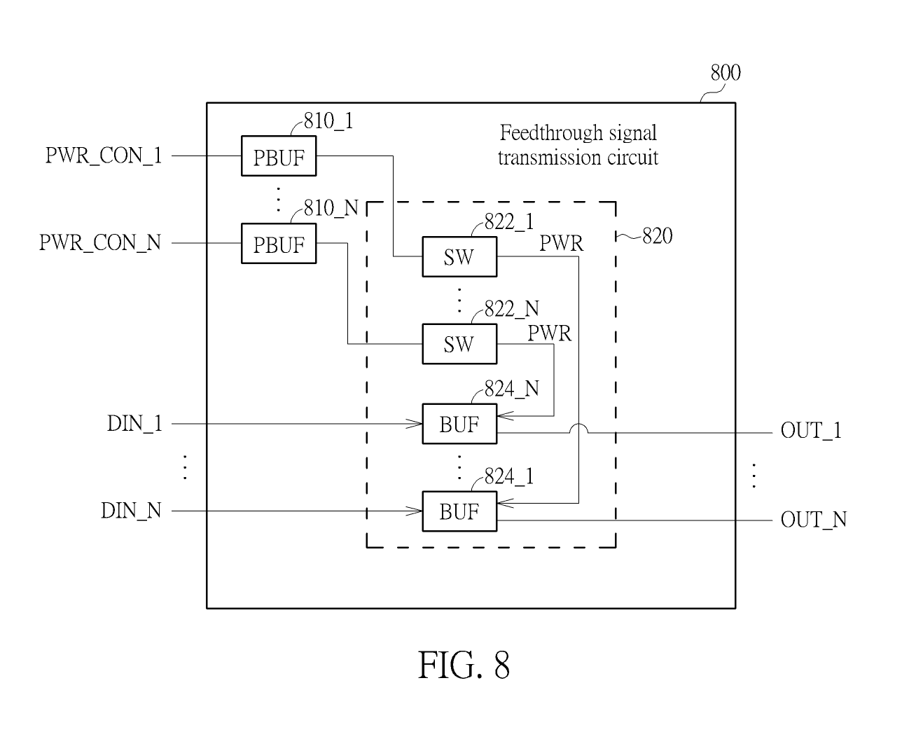

As mentioned above, a coarse-grained power gating topology is employed by the embodiments shown in FIG. 2 and FIG. 3. The same concept of the invention may also be applied to a feedthrough signal transmission circuit with a fine-grained power gating topology. Please refer to FIG. 8, which shows a feedthrough signal transmission circuit 800 according to a third embodiment of the invention. The feedthrough signal transmission circuit 800 includes a plurality of permanently on cells 810_1-810_N (also denoted by ‘PBUF’) and a cell controlling unit 820, where the cell controlling unit 820 includes a plurality of power switches 822_1-822_N (also denoted by ‘SW’) and a plurality of buffers 824_1-824_N (also denoted by ‘BUF’). By way of example, but not limitation, each of the power switches 822_1-822_N may be implemented using a multi-threshold complementary metal-oxide-semiconductor (MTCMOS) transistor. The buffers 824_1-824_N are normal buffers which serve as feedthrough buffers. As the cell controlling unit 820 is configured in a fine-grained fashion, multiple power switches (i.e. 822_1-822_N) are controlled by multiple control signals (i.e. PWR_CON_1-PWR_CON_N transmitted by permanently on cells 810_1-810_N), respectively, and multiple power switches (i.e. 822_1-822_N) are responsible for controlling the power supply PWR of multiple buffers (i.e. 824_1-824_N), respectively. The operation and function of each of the permanently on cells 810_1-810_N are the same as that of the permanently on cell 210; the operation and function of each of the power switches 822_1-822_N are the same as that of the power switch 222; and the operation and function of each of the buffer 824_1-824_N are the same as that of each of the buffers 224_1-244_N. The operational status of each of the buffers 822_1-822_N is individually controlled by a corresponding power switch. As the feedthrough buffers implemented using normal buffers can be powered down as needed, the same objective of reducing the leakage power consumption of a feedthrough signal transmission circuit is achieved.

In the example shown in FIG. 8, no repeater is included in the feedthrough signal transmission circuit 800. This is for illustrative purposes only. In an alternative design, the feedthrough signal transmission circuit 800 may be modified to include the aforementioned repeaters 230_1-230_N shown in FIG. 2, and this also belongs to the scope of the invention.

According to some embodiments of the invention, a feedthrough signal transmission apparatus that is fabricated on an integrated circuit (IC) such as a single silicon may comprise a plurality of feedthrough signal transmission circuits, where a feedthrough signal transmission circuit within the plurality of feedthrough signal transmission circuits (e.g. each feedthrough signal transmission circuit of the plurality of feedthrough signal transmission circuits, or each feedthrough signal transmission circuit of a portion of the plurality of feedthrough signal transmission circuits) may comprise at least one sub-circuit (e.g. one or more sub-circuits) that may be kept in a power on state when the sub-circuit performs feedthrough signal transmission. Thus, the aforementioned at least one sub-circuit may be kept in the power on state for feedthrough signal transmission. For example, the aforementioned at least one sub-circuit may be kept in the power on state for feedthrough signal transmission when the power of some other portion(s) in the feedthrough signal transmission circuit is turned off. For another example, the aforementioned at least one sub-circuit may be kept in the power on state for feedthrough signal transmission, no matter whether the power of some other portion(s) in the feedthrough signal transmission circuit can be turned off. For yet another example, when the feedthrough signal transmission apparatus is operating (e.g. the power of the feedthrough signal transmission apparatus is not turned off), the aforementioned at least one sub-circuit may always be kept in the power on state for feedthrough signal transmission.

No matter whether the power of the aforementioned at least one sub-circuit can be individually turned on or off, and no matter whether the power of some other portion(s) in the feedthrough signal transmission circuit can be individually turned one or off, the aforementioned at least one sub-circuit may be kept in the power on state when needed (e.g. for feedthrough signal transmission). More particularly, the aforementioned at least one sub-circuit may comprise at least one repeater (e.g. one or more repeaters) that may be kept in the power on state when needed (e.g. for feedthrough signal transmission). For example, when the aforementioned at least one sub-circuit performs feedthrough signal transmission, the aforementioned at least one repeater may be kept in the power on state for feedthrough signal transmission. As the aforementioned at least one repeater may be kept in the power on state for feedthrough signal transmission, the aforementioned at least one repeater may be referred to as at least one permanently on-for-feedthrough repeater. Examples of the aforementioned at least one permanently on-for-feedthrough repeater may include, but not limited to, a normal buffer (e.g. a buffer powered by a power supply signal output from a power switch such as that mentioned above, or a buffer that is normally powered without using a power switch such as that mentioned above), a permanently on buffer (e.g. a buffer that is permanently turned on, as long as the feedthrough signal transmission apparatus is operating), etc. In addition to the plurality of feedthrough signal transmission circuits, the feedthrough signal transmission apparatus may further comprise a permanently on control cell that is coupled to the plurality of feedthrough signal transmission circuits. For example, the permanently on control cell may be configured to maintain the power on state of the aforementioned at least one sub-circuit when the aforementioned at least one sub-circuit performs feedthrough signal transmission.

Please note that any of the feedthrough signal transmission circuit 200 or the feedthrough signal transmission circuit 300 may be taken as an example of this feedthrough signal transmission circuit. For example, the feedthrough signal transmission circuit within the plurality of feedthrough signal transmission circuits may comprise a power island circuit (which can also be referred to as “power island” for brevity), and the power island circuit may comprise at least one power switch (e.g. one or more power switches), and may further comprise multiple repeaters controlled by the aforementioned at least one power switch, such as a set of buffers or a set of inverter pairs under the same polarity, for transmitting signals from a signal source in one power domain to a signal sink in another power domain. Examples of the repeaters controlled by the aforementioned at least one power switch may include, but not limited to, the plurality of buffers 224_1-224_N shown in FIG. 2, and the plurality of buffers 824_1-824_N shown in FIG. 8, where each of the cell controlling unit 220 shown in any of FIGS. 2-3, the associated cell controlling unit in any of the embodiments respectively shown in FIGS. 4-7, and the cell controlling unit 820 shown in FIG. 8 can be regarded as an example of the power island circuit. Taking the plurality of buffers 224_1-224_N as an example of the plurality of repeaters, as each of the plurality of buffers 224_1-224_N may be implemented to be much smaller than a permanently on buffer (or a permanently on cell), and as the plurality of buffers 224_1-224_N may share some common architecture (e.g. the common wiring and boundary isolation architecture of the power island circuit), the chip area for implementing the plurality of buffers 224_1-224_N may be much smaller than that for implementing N permanently on buffers. In some embodiments, the feedthrough signal transmission circuit may comprise more than one power island circuit when needed. For example, in a situation where the distance between the signal source and the signal sink is long, the feedthrough signal transmission circuit may comprise multiple power island circuits that are coupled (e.g. one is coupled to another) to form the signal transmission paths between the signal source and the signal sink.

According to some embodiments of the invention, sub-circuits of a set of feedthrough signal transmission circuits within the plurality of feedthrough signal transmission circuits, such as the power island circuits of the set of feedthrough signal transmission circuits, may be located at grid-based locations on a chip area of the IC (e.g. a chip area of the single silicon), respectively, where the set of feedthrough signal transmission circuits may comprise at least one portion (e.g. a portion or all) of the plurality of feedthrough signal transmission circuits. For example, the grid-based locations may comprise at least one portion (e.g. a portion or all) of a plurality of grid locations on the chip area of the IC (e.g. the chip area of the single silicon), such as the plurality of grid locations corresponding to a grid pitch. The typical value of the grid pitch of the plurality of grid locations may be greater than the size(s) of the sub-circuits of the set of feedthrough signal transmission circuits, such as the power island circuits of the set of feedthrough signal transmission circuits. For example, the grid pitch of the plurality of grid locations may be greater than or equal to several times the size of the power island circuit of the feedthrough signal transmission circuit. In addition, at least one portion (e.g. a portion or all) of the sub-circuits of the set of feedthrough signal transmission circuits may be located at the aforementioned at least one portion of the plurality of grid locations, respectively. For brevity, similar descriptions for these embodiments are not repeated in detail here.

According to some embodiments, the grid-based locations may comprise grid-with-offset locations on the chip area of the IC (e.g. the chip area of the single silicon), and any of the grid-with-offset locations is a location deviated from one of the plurality of grid locations on the chip area of the IC by a location offset. In addition, at least one portion (e.g. a portion or all) of the sub-circuits of the set of feedthrough signal transmission circuits may be located at the grid-with-offset locations, respectively. For brevity, similar descriptions for these embodiments are not repeated in detail here.

According to some embodiments, the location offset may comprise at least one location offset component corresponding to at least one grid-line direction on the chip area of the IC (e.g. an offset component corresponding to a grid-line direction such as the X-direction or the Y-direction on the chip area of the IC, or two offset components respectively corresponding to two grid-line directions such as the X-direction and the Y-direction on the chip area of the IC), and each location offset component within the aforementioned at least one location offset may be less than or equal to a half of the grid pitch of the plurality of grid locations. For brevity, similar descriptions for these embodiments are not repeated in detail here.

According to some embodiments, the grid-based locations may comprise the aforementioned at least one portion of the plurality of grid locations and may further comprise the grid-with-offset locations, where a portion of the set of feedthrough signal transmission circuits may be located at the aforementioned at least one portion of the plurality of grid locations, respectively, and another portion of the set of feedthrough signal transmission circuits may be located at the grid-with-offset locations, respectively. For brevity, similar descriptions for these embodiments are not repeated in detail here.

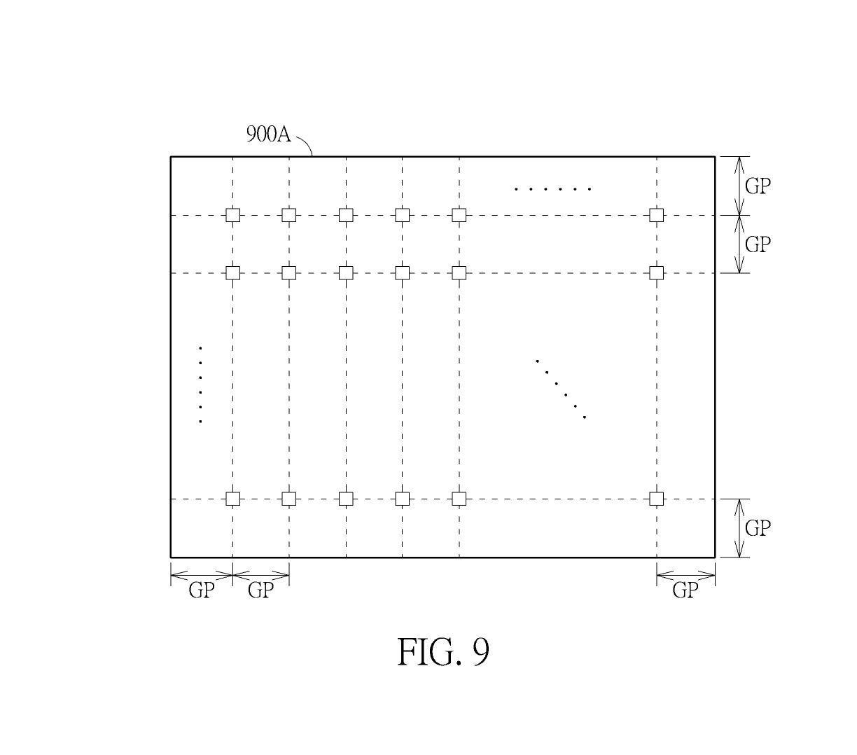

FIG. 9 illustrates some grid locations on a chip area 900A according to an embodiment of the invention, where the chip area 900A can be taken as an example of the chip area of the IC mentioned above, and the notation “GP” may represent the grid pitch. As shown in FIG. 9, the dashed lines may represent the power mesh such as the associated grid lines for determining the grid-based locations, and the intersections of these grid lines may represent at least one portion (e.g. a portion or all) of the plurality of grid locations. For example, the small boxes illustrated in FIG. 9 may indicate a typical size of the set of feedthrough signal transmission circuits, where the grid pitch of the plurality of grid locations is typically greater than the size of the feedthrough signal transmission circuit, and more particularly, may be greater than or equal to several times the size of any of the set of feedthrough signal transmission circuits. This is for illustrative purposes only, and is not meant to be a limitation of the invention. According to some embodiments, the typical size of the set of feedthrough signal transmission circuits may vary. According to some embodiments, the set of feedthrough signal transmission circuits may have the same size. According to some embodiments, it is unnecessary that the set of feedthrough signal transmission circuits has the same size. For example, the sizes of one or more feedthrough signal transmission circuits within the set of feedthrough signal transmission circuits may be different from that of one or more other feedthrough signal transmission circuits within the set of feedthrough signal transmission circuits.

For better comprehension, the small boxes are illustrated at the grid points such as the intersections of these grid lines, respectively, to indicate the candidate locations of a plurality of power islands such as the plurality of feedthrough signal transmission circuits. For example, under control of a design-tool device for the power engineer/designer of the IC, such as a computer having at least one processor running a set of computer program codes, the grid lines and the small boxes may be displayed on a display module of the design-tool device (e.g. a liquid crystal display (LCD) module within the design-tool device, or an LCD monitor coupled to the design-tool device). This is for illustrative purposes only, and is not meant to be a limitation of the invention. According to some embodiments, it is unnecessary that all of the intersections of these grid lines are utilized as the candidate locations of the plurality of power islands such as the plurality of feedthrough signal transmission circuits. Please note that, no matter whether all of the intersections of these grid lines are utilized as the candidate locations of the plurality of power islands such as the plurality of feedthrough signal transmission circuits, during a design phase of the IC, the grid-based locations can be automatically determined by the design-tool device, where the power engineer/designer of the IC may set up or input some initial parameters such as initial placement parameters of some components of the IC into the design-tool device such as the computer having the processor running the set of computer program codes, to allow the computer to start automatically determining the grid-based locations. For example, the set of computer program codes may be written according to a wave-propagation based power island algorithm for determining locations of the plurality of power islands such as the plurality of feedthrough signal transmission circuits to be the grid-based locations.

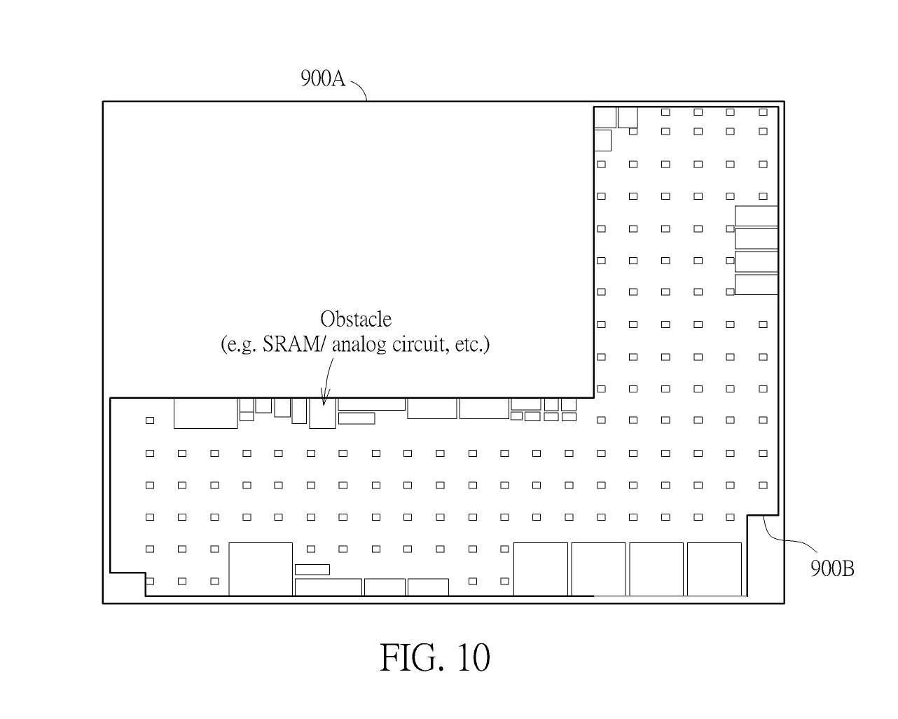

FIG. 10 illustrates some grid locations on a chip area 900B according to another embodiment of the invention, where the chip area 900B can also be taken as an example of the chip area of the IC mentioned above. For example, the chip area 900B shown in FIG. 10 may be within the chip area 900A of the embodiment shown in FIG. 9. For clarity and simplicity, the dashed lines shown in FIG. 9 are not illustrated in FIG. 10, while some small boxes located within the chip area 900B shown in FIG. 10 may still be illustrated in this embodiment. For example, the small boxes of this embodiment may be illustrated in the chip area 900B shown in FIG. 10, to indicate the typical size of the set of feedthrough signal transmission circuits, where the grid pitch of the plurality of grid locations is typically greater than the size of the feedthrough signal transmission circuit, and more particularly, may be greater than or equal to several times the size of any of the set of feedthrough signal transmission circuits. This is for illustrative purposes only, and is not meant to be a limitation of the invention. According to some embodiments, the typical size of the set of feedthrough signal transmission circuits may vary. According to some embodiments, the set of feedthrough signal transmission circuits may have the same size. According to some embodiments, it is unnecessary that the set of feedthrough signal transmission circuits has the same size. For example, the sizes of one or more feedthrough signal transmission circuits within the set of feedthrough signal transmission circuits may be different from that of one or more other feedthrough signal transmission circuits within the set of feedthrough signal transmission circuits.

According to this embodiment, there may be some obstacles to the set of feedthrough signal transmission circuits. Examples of the obstacles may include, but not limited to, static random access memories (SRAMs), and analog circuits. As shown in FIG. 10, the small boxes of this embodiment may be located at virtual grid points (e.g. intersection points of virtual grid lines that are not displayed on the display module of the design-tool device for the power engineer/designer of the IC), except for those having the obstacles (e.g. the SRAMs, the analog circuits, etc.), respectively. For brevity, similar descriptions for this embodiment are not repeated in detail here.

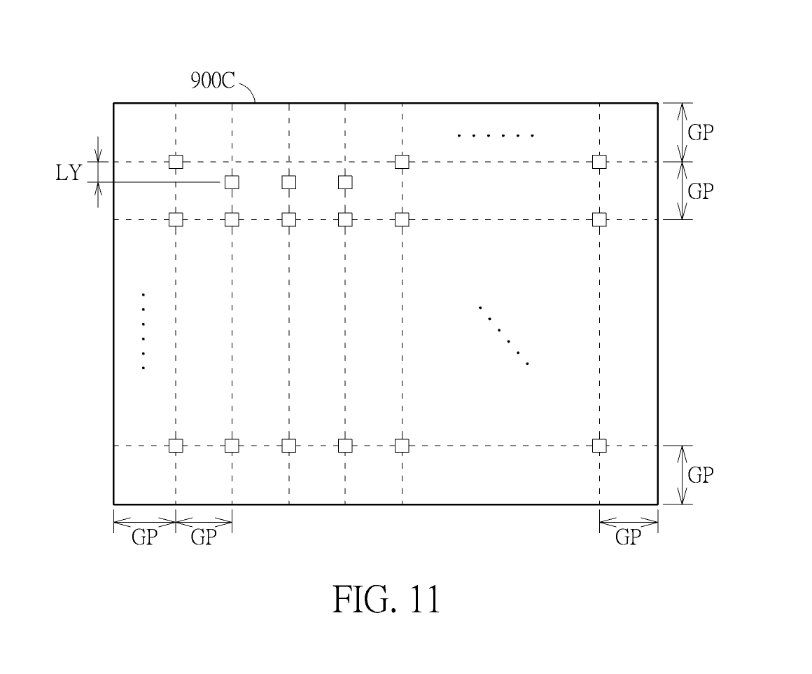

FIG. 11 illustrates some grid-with-offset locations on a chip area 900C according to an embodiment of the invention, where the chip area 900C can also be taken as an example of the chip area of the IC mentioned above. In comparison with the embodiment shown in FIG. 9, the locations of three small boxes within the small boxes shown in FIG. 9 are deviated from the original grid locations thereof, respectively, by a location offset comprising the offset component LY corresponding to the Y-direction in this embodiment, where this location offset may be regarded as a location offset vector (0,LY). Please note that the locations of the three small boxes in this embodiment can be taken as examples of the grid-with-offset locations on the chip area of the IC mentioned above. For example, during the design phase of the IC, the design-tool device (e.g. the computer having the processor running the set of computer program codes) may automatically determine the grid-based locations by deviating the candidate locations of the three small boxes within the small boxes shown in FIG. 9 from the original grid locations thereof by the location offset comprising the offset component LY (e.g. the location offset vector (0,LY)), respectively. For brevity, similar descriptions for this embodiment are not repeated in detail here.

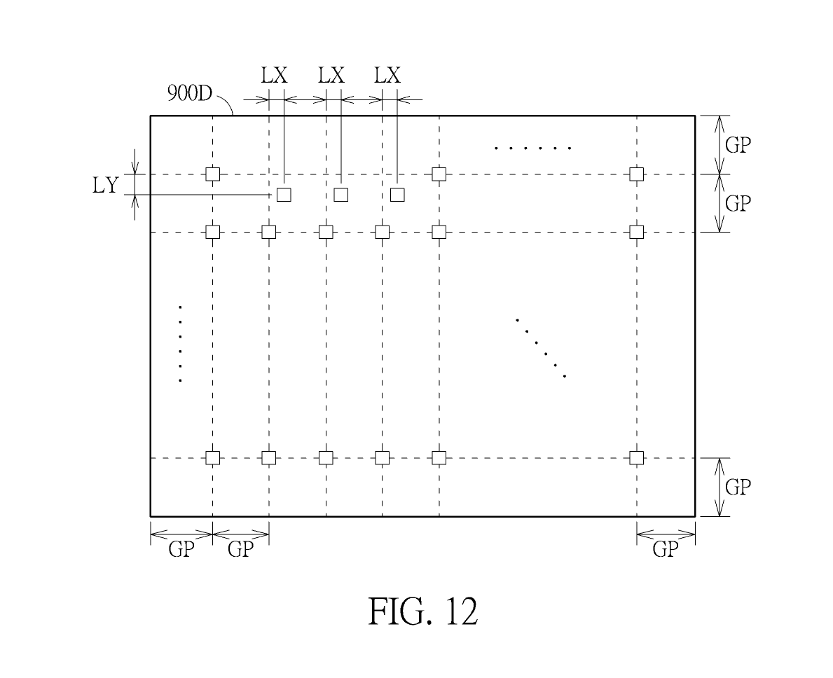

FIG. 12 illustrates some grid-with-offset locations on a chip area 900D according to another embodiment of the invention, where the chip area 900D can also be taken as an example of the chip area of the IC mentioned above. In comparison with the embodiment shown in FIG. 9, the locations of the aforementioned three small boxes within the small boxes shown in FIG. 9 are deviated from the original grid locations thereof, respectively, by a location offset comprising the offset components LX and LY respectively corresponding to the X-direction and the Y-direction in this embodiment, where this location offset may be regarded as a location offset vector (LX,LY). Please note that the locations of the three small boxes in this embodiment can also be taken as examples of the grid-with-offset locations on the chip area of the IC mentioned above. For example, during the design phase of the IC, the design-tool device (e.g. the computer having the processor running the set of computer program codes) may automatically determine the grid-based locations by deviating the candidate locations of the three small boxes within the small boxes shown in FIG. 9 from the original grid locations thereof by the location offset comprising the location offset components LX and LY (e.g. the location offset vector (LX,LY)), respectively. For brevity, similar descriptions for this embodiment are not repeated in detail here.

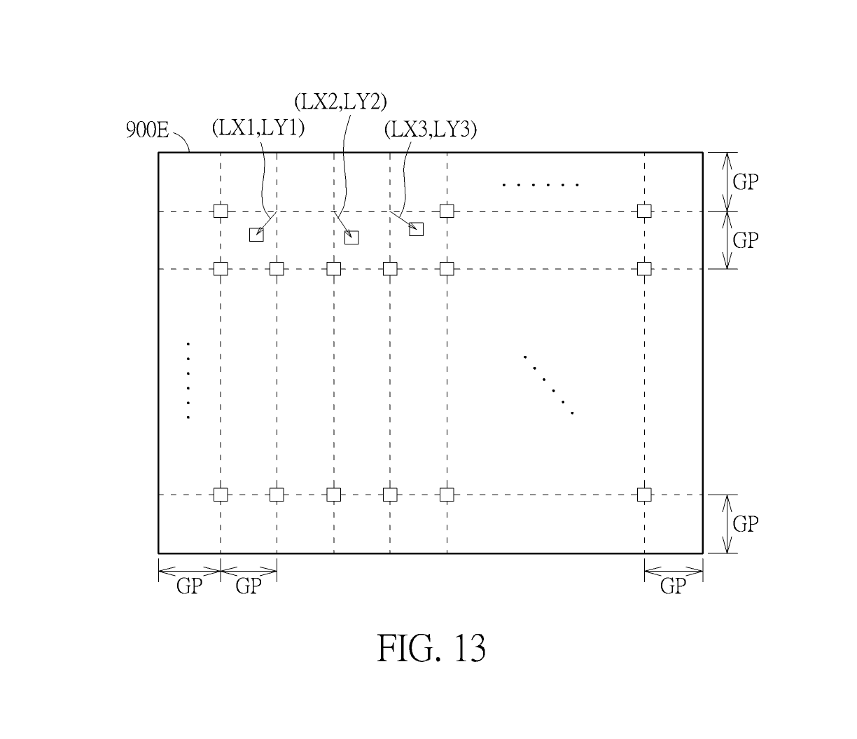

FIG. 13 illustrates some grid-with-offset locations on a chip area 900E according to yet another embodiment of the invention, where the chip area 900E can also be taken as an example of the chip area of the IC mentioned above. In comparison with the embodiment shown in FIG. 9, the locations of the aforementioned three small boxes within the small boxes shown in FIG. 9 are deviated from the original grid locations thereof by a plurality of location offsets, respectively. Examples of the plurality of location offsets may include, but not limited to, a first location offset comprising the offset components LX1 and LY1 respectively corresponding to the X-direction and the Y-direction (labeled “(LX1,LY1)” in FIG. 13, to indicate the corresponding location offset vector), a second location offset comprising the offset components LX2 and LY2 respectively corresponding to the X-direction and the Y-direction (labeled “(LX2,LY2)” in FIG. 13, to indicate the corresponding location offset vector), and a third location offset comprising the offset components LX3 and LY3 respectively corresponding to the X-direction and the Y-direction (labeled “(LX3,LY3)” in FIG. 13, to indicate the corresponding location offset vector). Please note that the locations of the three small boxes in this embodiment can also be taken as examples of the grid-with-offset locations on the chip area of the IC mentioned above. For example, during the design phase of the IC, the design-tool device (e.g. the computer having the processor running the set of computer program codes) may automatically determine the grid-based locations by deviating the candidate locations of the three small boxes within the small boxes shown in FIG. 9 from the original grid locations thereof by the plurality of location offsets (e.g. the location offset vectors (LX1,LY1), (LX2,LY2), and (LX3,LY3)), respectively. For brevity, similar descriptions for this embodiment are not repeated in detail here.

According to some embodiments, the plurality of feedthrough signal transmission circuits may comprise another set of feedthrough signal transmission circuits that are not equipped with any power switch such as that of some of the above embodiments (e.g. the power switch 222 shown in FIG. 2, or the power switches 822_1-822_N shown in FIG. 8), where the set of feedthrough signal transmission circuits described in some of the above embodiments may comprise one portion of the plurality of feedthrough signal transmission circuits, and the other set of feedthrough signal transmission circuits may comprise another portion of the plurality of feedthrough signal transmission circuits. In addition, some sub-circuits of the other set of feedthrough signal transmission circuits within the plurality of feedthrough signal transmission circuits, such as repeater clusters (e.g. buffer clusters) that are not controlled by any power switch, may be located at other grid-based locations on the chip area of the IC (e.g. the chip area of the single silicon), respectively, where each of the repeater clusters of the other set of feedthrough signal transmission circuits may comprise multiple repeaters (e.g. multiple normal buffers) arranged to perform feedthrough signal transmission. For example, in a situation where the grid-based locations merely comprise the portion (e.g. rather than all) of the plurality of grid locations on the chip area of the IC, the other grid-based locations may comprise another portion of the plurality of grid locations on the chip area of the IC (e.g. the chip area of the single silicon), such as the plurality of grid locations corresponding to the grid pitch. The typical value of the grid pitch of the plurality of grid locations may be greater than the size(s) of the sub-circuits of the other set of feedthrough signal transmission circuits, such as the repeater clusters (e.g. the buffer clusters) of the other set of feedthrough signal transmission circuits. For example, the grid pitch of the plurality of grid locations may be greater than or equal to several times the size of any of the repeater clusters of the other set of feedthrough signal transmission circuits. In addition, at least one portion (e.g. a portion or all) of the sub-circuits of the other set of feedthrough signal transmission circuits may be located at the other portion of the plurality of grid locations, respectively. For brevity, similar descriptions for these embodiments are not repeated in detail here.

According to some embodiments, the other grid-based locations may comprise other grid-with-offset locations on the chip area of the IC (e.g. the chip area of the single silicon), and any of the other grid-with-offset locations is a location deviated from one of the plurality of grid locations on the chip area of the IC by a location offset such as that mentioned above. In addition, at least one portion (e.g. a portion or all) of the sub-circuits of the other set of feedthrough signal transmission circuits may be located at the grid-with-offset locations, respectively. For brevity, similar descriptions for these embodiments are not repeated in detail here.

According to some embodiments, the other grid-based locations may comprise the other portion of the plurality of grid locations and may further comprise the other grid-with-offset locations, where a portion of the sub-circuits of the other set of feedthrough signal transmission circuits may be located at the other portion of the plurality of grid locations, respectively, and another portion of the sub-circuits of the other set of feedthrough signal transmission circuits may be located at the other grid-with-offset locations, respectively. For brevity, similar descriptions for these embodiments are not repeated in detail here.

According to some embodiments, permanently on cells that receive and transmit control signals to control operations of the plurality of feedthrough signal transmission circuits, such as the plurality of permanently on cells 210 and 250 shown in FIG. 2 and the permanently on cells 810_1-810_N shown in FIG. 8, may be regarded as permanently on cells for control purposes, and therefore may be referred to as permanently on control cells. For example, the permanently on control cells may be implemented with permanently on buffers. In addition, some repeaters for control purposes that are not controlled by any power switch, such as that labeled “ISO” in FIGS. 2 and 5-7 (e.g. the repeaters 230_1-230_N shown in FIG. 2, the repeater 506 shown in FIG. 5, the repeater 606 shown in FIG. 6, and the repeaters 706 and 708 shown in FIG. 7), may be regarded as permanently on repeaters for control purposes. Additionally, repeaters that are controlled by one or more power switches, such as that labeled “BUF” in FIGS. 2-8 (e.g. the buffers 224_1-224_N shown in any of FIGS. 2-3, the buffer labeled “BUF” in any of FIGS. 4-7, and the buffers 824_1-824_N shown in FIG. 8), may be regarded as non-permanently on repeaters. For example, these non-permanently on repeaters may be kept in a power on state such as that mentioned above when the associated sub-circuits (e.g. the power islands) perform feedthrough signal transmission, and therefore these non-permanently on repeaters may be regarded as permanently on-for-feedthrough repeaters, which can be taken as examples of the permanently on-for-feedthrough repeater mentioned above. Please note that the repeaters in any of the repeater clusters mentioned above may also be kept in a power on state such as that mentioned above when the associated sub-circuits (e.g. the repeater clusters) perform feedthrough signal transmission, and therefore these repeaters may also be regarded as permanently on-for-feedthrough repeaters, which can be taken as examples of the permanently on-for-feedthrough repeater mentioned above. Thus, any repeater that may be kept in a power on state such as that mentioned above when the associated sub-circuit comprising this repeater performs feedthrough signal transmission can be regarded as a permanently on-for-feedthrough repeater since it is ready for feedthrough signal transmission.

According to some embodiments, the other set of feedthrough signal transmission circuits may comprise all of the plurality of feedthrough signal transmission circuits. For brevity, similar descriptions for these embodiments are not repeated in detail here.

It is an advantage of the invention that, as feedthrough buffers implemented using normal buffers can be powered down as needed, the feedthrough signal transmission circuit and the associated method can greatly reduce leakage power consumption. In addition, the set of feedthrough signal transmission circuits within the plurality of feedthrough signal transmission circuits may be located at the grid-based locations on the chip area of the IC, respectively. During the design phase of the IC, the grid-based locations can be automatically determined with aid of the set of computer program codes, rather than being manually determined by the power engineer/designer of the IC. As the time required for automatically determining the grid-based locations with the aid of the set of computer program codes (e.g. a half of a day) is less than the time required for manually determining non-grid-based locations by the power engineer/designer (e.g. one or more days), the invention can save time of the power engineer/designer during the design phase of the IC. Therefore, in comparison with the prior art, power engineers/designers of the feedthrough signal transmission circuit implemented according to the invention can design in a time efficient manner (e.g. with aid of the set of computer program codes).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A feedthrough signal transmission apparatus, fabricated on a single silicon, comprising:
a plurality of feedthrough signal transmission circuits, wherein each feedthrough signal transmission circuit of the feedthrough signal transmission circuits comprises at least one sub-circuit that is kept in a power on state when the sub-circuit performs feedthrough signal transmission, and the sub-circuit comprises:
a permanently on-for-feedthrough repeater; and
a permanently on control cell, coupled to the plurality of feedthrough signal transmission circuits, configured to maintain the power on state of the sub-circuit when the sub-circuit performs feedthrough signal transmission;
wherein sub-circuits of the feedthrough signal transmission circuits are located at grid-based locations on a chip area of the single silicon.

2. The feedthrough signal transmission apparatus of claim 1, wherein the sub-circuit is a power island circuit, and the power island circuit comprises at least one power switch and multiple repeaters controlled by the at least one power switch.

3. The feedthrough signal transmission apparatus of claim 2, wherein the repeaters comprise:
a set of buffers or a set of inverter pairs under the same polarity.

4. The feedthrough signal transmission apparatus of claim 2, wherein the at least one power switch comprises a multi-threshold complementary metal-oxide-semiconductor (MTCMOS) transistor.

5. The feedthrough signal transmission apparatus of claim 1, wherein the sub-circuit is a repeater cluster, and the repeater cluster comprises multiple repeaters.

6. The feedthrough signal transmission apparatus of claim 4, wherein the repeaters comprise:
a set of buffers or a set of inverter pairs under the same polarity.

7. The feedthrough signal transmission apparatus of claim 1, wherein the sub-circuit comprises at least one power switch for keeping the sub-circuit in the power on state when the sub-circuit performs feedthrough signal transmission, and the at least one power switch comprises a multi-threshold complementary metal-oxide-semiconductor (MTCMOS) transistor.

8. The feedthrough signal transmission apparatus of claim 1, wherein the grid-based locations comprise at least one portion of a plurality of grid locations on the chip area of the single silicon; and at least one portion of the sub-circuits of the feedthrough signal transmission circuits is located at the at least one portion of the plurality of grid locations, respectively.

9. The feedthrough signal transmission apparatus of claim 8, wherein a grid pitch of the plurality of grid locations is greater than the size(s) of the sub-circuits of the feedthrough signal transmission circuits.

10. The feedthrough signal transmission apparatus of claim 9, wherein the sub-circuit is a power island circuit, and the power island circuit comprises at least one power switch and multiple repeaters controlled by the at least one power switch.

11. The feedthrough signal transmission apparatus of claim 9, wherein the sub-circuit is a repeater cluster, and the repeater cluster comprises multiple repeaters.

12. The feedthrough signal transmission apparatus of claim 1, wherein the grid-based locations comprise grid-with-offset locations on the chip area of the single silicon, and any of the grid-with-offset locations is a location deviated from one of a plurality of grid locations on the chip area of the single silicon by a location offset; and at least one portion of the sub-circuits of the feedthrough signal transmission circuits is located at the grid-with-offset locations, respectively.

13. The feedthrough signal transmission apparatus of claim 12, wherein a grid pitch of the plurality of grid locations is greater than the size(s) of the sub-circuits of the feedthrough signal transmission circuits.

14. The feedthrough signal transmission apparatus of claim 13, wherein the sub-circuit is a power island circuit, and the power island circuit comprises at least one power switch and multiple repeaters controlled by the at least one power switch.

15. The feedthrough signal transmission apparatus of claim 13, wherein the sub-circuit is a repeater cluster, and the repeater cluster comprises multiple repeaters.

16. A feedthrough signal transmission method, applied to a feedthrough signal transmission apparatus that is fabricated on a single silicon, comprising:
transmitting a control signal to a permanently on control cell, wherein the feedthrough signal transmission apparatus comprises a plurality of feedthrough signal transmission circuits and the permanently on control cell; and
according to the control signal, utilizing the permanently on control cell to maintain a power on state of at least one sub-circuit of each of the feedthrough signal transmission circuits when the sub-circuit performs feedthrough signal transmission;
wherein sub-circuits of the feedthrough signal transmission circuits are located at grid-based locations on a chip area of the single silicon.

17. The feedthrough signal transmission method of claim 16, wherein the grid-based locations comprise at least one portion of a plurality of grid locations on the chip area of the single silicon; and at least one portion of the sub-circuits of the feedthrough signal transmission circuits is located at the at least one portion of the plurality of grid locations, respectively.

18. The feedthrough signal transmission method of claim 16, wherein the grid-based locations comprise grid-with-offset locations on the chip area of the single silicon, and any of the grid-with-offset locations is a location deviated from one of a plurality of grid locations on the chip area of the single silicon by a location offset; and at least one portion of the sub-circuits of the feedthrough signal transmission circuits is located at the grid-with-offset locations, respectively.

19. A feedthrough signal transmission circuit that operates according to the feedthrough signal transmission method of claim 16, wherein the feedthrough signal transmission circuit is one of the feedthrough signal transmission circuits.
